(19) United States
(12) Patent Application Publication
(10) Pub. No.: US 2019/0232433 A1
(43) Pub. Date: Aug. 1, 2019

(54) SLICING METHOD AND SLICING APPARATUS

(71) Applicant: PANASONIC CORPORATION, Osaka (JP)

(72) Inventors: Yoshiro KITAMURA, Osaka (JP); Kazuki FUJIWARA, Osaka (JP); Katsuji SUMIMOTO, Nara (JP); Takeshi OHMORI, Osaka (JP)

(21) Appl. No.: 16/263,382

(22) Filed: Jan. 31, 2019

(30) Foreign Application Priority Data
Feb. 1, 2018 (JP) 2018-016347
Nov. 8, 2018 (JP) 2018-210458

(51) Int. Cl. B23K 26/38; B23K 26/40; H01L 21/304; B23K 26/53

(52) U.S. Cl. CPC B23K 26/38; B23K 26/53; H01L 21/304; B23K 26/40

(57) ABSTRACT

Provided are a slicing method and a slicing apparatus, which prevent a trouble that occurs when a workpiece having a modified layer formed therein is separated at the modified layer as a boundary. Separation apparatus 200 includes: heating apparatus 12 for melting modified layer 8 of workpiece 1 formed by collection of a laser beam, by heating modified layer 8 at a temperature that is less than a melting point of workpiece 1 and equal to or more than a melting point of modified layer 8; and separation jig 11 for separating workpiece 1 at melted modified layer 8 as a boundary.

### CROSS REFERENCE TO RELATED APPLICATIONS

This application is entitled to and claims the benefit of Japanese Patent Application No. 2018-016347, filed on Feb. 1, 2018, and Japanese Patent Application No. 2018-210458, filed on Nov. 8, 2018, the disclosure of which including the specification, drawings and abstract is incorporated herein by reference in its entirety.

### TECHNICAL FIELD

The present invention relates to a slicing method and a slicing apparatus.

### BACKGROUND ART

As one method of manufacturing a substrate (wafer) from a hard brittle material such as silicon (Si), gallium nitride (GaN), silicon carbide (SiC), sapphire, or diamond, there is given a method of forming a modified layer inside a hard brittle material using laser and separating the hard brittle material into a wafer shape at the modified layer as a boundary.

For example, in PTL 1, the following method is disclosed. Specifically, in a slicing step for a silicon wafer, a focus point of a laser beam is adjusted to an inside of a workpiece by a condenser lens, and the workpiece is scanned with the laser beam, to thereby form a planar processing region. Then, a part of the workpiece is separated as a substrate at the processing region as a boundary using expansion and shrinkage caused by heat generated inside the workpiece.

### CITATION LIST

### Patent Literature

PTL 1

Japanese Patent Application Laid-Open No. 2011-60860

### SUMMARY OF INVENTION

### Technical Problem

However, in the related-art method described above, when the hard brittle material is used as the workpiece, chipping may occur in the vicinity of a portion into which a wedge-shaped press-fitting member is press-fitted or a moment may act in a direction in which the wafer is warped. Thus, the wafer itself may be broken or otherwise damaged.

An object of the present disclosure is to provide a slicing method and a slicing apparatus, which are capable of preventing a trouble that occurs when a workpiece having a modified layer formed therein is separated at the modified layer as a boundary.

### Solution to Problem

A slicing method according to one aspect of the present disclosure includes: a modified-layer melting step of melting a modified layer of a workpiece by heating the modified layer at a temperature that is less than a melting point of the workpiece and is equal to or more than a melting point of the modified layer, the workpieces being formed by collection of a laser beam; and a separating step of separating the workpiece at the melted modified layer as a boundary

A slicing apparatus according to one aspect of the present disclosure includes: a heating section that melts a modified layer of a workpiece by heating the modified layer at a temperature that is less than a melting point of the workpiece and is equal to or more than a melting point of the modified layer, the workpieces being formed by collection of a laser beam; and a separation section that separates the workpiece at the melted modified layer as a boundary.

### Advantageous Effects of Invention

With the slicing method and the slicing apparatus according to the present disclosure, it is possible to prevent a trouble that occurs when the workpiece having the modified layer formed therein is separated at the modified layer as a boundary.

### BRIEF DESCRIPTION OF DRAWINGS

FIG. 1 is a schematic view illustrating an example of a laser processing apparatus according to an embodiment of the present disclosure;

FIG. 2A is a schematic view illustrating an example of a moving direction of a workpiece during a modified-layer forming operation according to the embodiment of the present disclosure;

FIG. 2B is a schematic view illustrating an example of the moving direction of the workpiece during the modified-layer forming operation according to the embodiment of the present disclosure;

FIG. 2C illustrates an example of a laser-irradiation pulse interval according to the embodiment of the present disclosure;

FIG. 3A is a schematic view illustrating a cross section of the workpiece during the modified-layer forming operation according to the embodiment of the present disclosure;

FIG. 3B is a schematic view illustrating a cross section of the workpiece during the modified-layer forming operation according to the embodiment of the present disclosure;

FIG. 3C is a schematic view illustrating a cross section of the workpiece during the modified-layer forming operation according to the embodiment of the present disclosure;

FIG. 4A is a schematic view illustrating a cross section of the workpiece after a modified layer is formed according to the embodiment of the present disclosure;

FIG. 4B is a schematic view illustrating a cross section of the workpiece after the modified layer is formed according to the embodiment of the present disclosure;

FIG. 5 is a schematic view of a separation apparatus according to the embodiment of the present disclosure;

FIG. 6A is a schematic view illustrating a cross section of the workpiece during a workpiece separating operation according to the embodiment of the present disclosure;

FIG. 6B is a schematic view illustrating a cross section of the workpiece during the workpiece separating operation according to the embodiment of the present disclosure;

FIG. 7 is a schematic view illustrating an example of a thickness of the modified layer according to the embodiment of the present disclosure;

FIG. 8 is a schematic view illustrating a cross section of the workpiece having a plurality of modified layers formed therein according to the embodiment of the present disclosure;

FIG. 9 is a perspective view illustrating the workpiece having the modified layer formed therein according to the embodiment of the present disclosure;

FIG. 10A is a schematic view illustrating a state in which an upper portion and a lower portion of the workpiece are turned in a horizontal direction according w the embodiment of the present disclosure as viewed from directly above;

FIG. 10B is a schematic view illustrating a state before an end surface of the workpiece in an XZ plane is turned according to the embodiment of the present disclosure;

FIG. 10C is a schematic view illustrating a state after the end surface illustrated in FIG. 10B is turned;

FIG. 11A is a schematic view illustrating a state in which the upper portion and the lower portion of the workpiece are inclined in a Z direction according to the embodiment of the present disclosure:

FIG. 11B is a schematic view illustrating a state before an end surface of the workpiece in a YZ plane is inclined according to the embodiment of the present disclosure; and

FIG. 11C is a schematic view illustrating a state after the end surface illustrated in FIG. 11B is inclined.

### DESCRIPTION OF EMBODIMENTS

Hereinafter, an embodiment of the present disclosure is described with reference to the accompanying drawings. Note that, in the accompanying drawings, common constituent elements are denoted by the same reference symbols, and description of those constituent elements is omitted as appropriate.

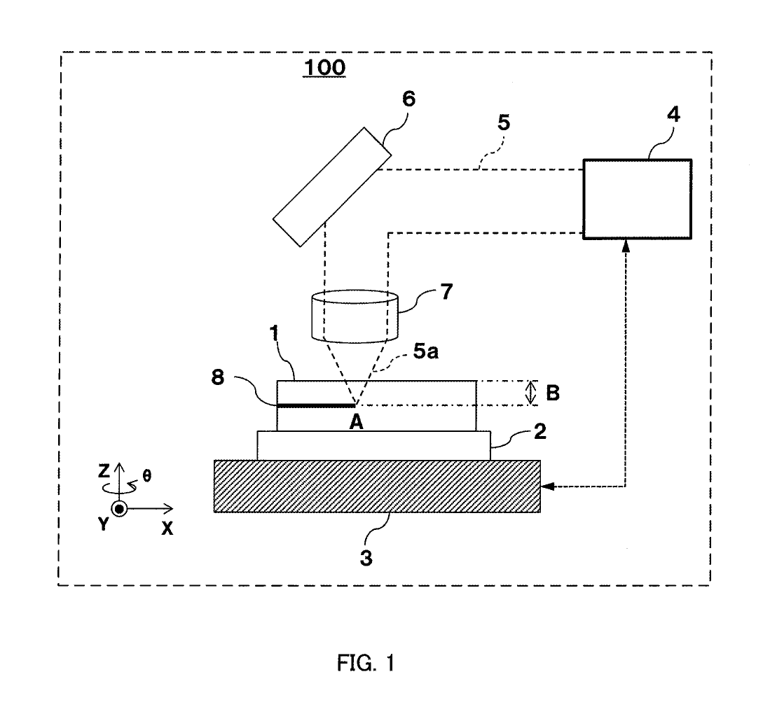

A configuration of laser processing apparatus (modified-layer forming apparatus) 100 according to the embodiment of the present disclosure is described. FIG. 1 is a schematic view of laser processing apparatus 100 according to this embodiment.

Laser processing apparatus 100 includes fixing table 2, drive stage 3, laser oscillator 4, mirror 6, and lens 7.

Workpiece 1 is formed of, for example, gallium nitride (an example of a hard brittle material; hereinafter, also referred to as GaN), and is a member to be processed, inside which modified layer 8 described later is to be processed. It is preferred that workpiece 1 have, for example, a diameter of 2 inches and a thickness of 400 μm. However, the diameter and the thickness are not limited to the above-mentioned values. There may be used an ingot material having a thickness larger than 400 μm, or an ingot material having a diameter larger than 2 inches.

Fixing table 2 fixes workpiece 1 by, for example, vacuum suction. Note that, as fixing table 2, a member that does not cause positional displacement of workpiece 1 through drive of drive stage 3 described later is used.

Drive stage 3 is drivable in an X-axis direction, a Y-axis direction, and a Z-axis direction, and is turnable in a θ direction. Further, drive stage 3 can control a relative position of laser beam 5 with respect to workpiece 1.

Laser oscillator 4 emits, onto workpiece 1, laser beam 5 being linearly polarized light having, for example, a diameter of about 4 mm. For example, laser beam 5 is picosecond laser having a wavelength with a transmittance of 50% or more (for example, a wavelength of 532 nm), a pulse width of from 0.2 picoseconds or more to 100 picoseconds or less (for example, 15 picoseconds), and maximum output of 50 W. Further, a maximum repetition frequency of laser beam 5 is 1 MHz.

Further, laser oscillator 4 can control ON/OFF of laser beam 5 through communication of a control signal with drive stage 3 (arrows indicated by the broken lines in FIG. 1).

Note that, measurement of a transmittance is performed using, for example, a spectrophotometer equipped with an integrating sphere (V7100 manufactured by JASCO Corporation; not shown). The transmittance refers to a ratio of an amount of light transmitted through workpiece 1 (amount of light received by a photometer) to a total amount of light emitted from laser oscillator 4.

Mirror 6 reflects 90% or more of laser beam 5 emitted from laser oscillator 4 and can sent reflected laser beam 5 to lens 7. As mirror 6, for example, there may be used a dielectric multilayer film mirror that reflects laser beam 5 having a wavelength of 532 nm at a high reflectance.

Lens 7 is a lens that can correct an aberration caused when laser beam 5 is collected (when laser beam 5 is transmitted through workpiece) to an optimal aberration amount in accordance with a processing depth.

Focus point A of laser beam 5a (distal end portion of laser beam 5a) having been transmitted through lens 7 is adjusted at a position inside workpiece 1 which is distant from the front surface of workpiece 1 (upper surface in the drawing) by distance B.

As lens 7, there may be used, for example, a lens for a microscope with an aberration correction ring allowing laser beam 5 having a wavelength of 532 run to be transmitted therethrough, and the lens has a numerical aperture (NA) of 0.7 and a focal distance of 4 mm.

Further, mirror finishing is applied to at least a surface of lens 7, which allows laser beam 5 to enter, so that laser beam 5 has at least a transmittance of 50% or more with respect to workpiece 1.

Modified layer 8 is formed of a modified component of gallium nitride in the vicinity of focus point A, and is formed of a gallium (Ga) generated by decomposing GaN, dimer of gallium, and a GaxNy cluster. When modified layer 8 is to be formed, the thickness of modified layer 8 is adjusted to 20 μm or smaller. Meanwhile, modified layer 8 has a shape with irregularities depending on accuracy of drive stage 3, surface accuracy of fixing table 2 (workpiece 1), and the like.

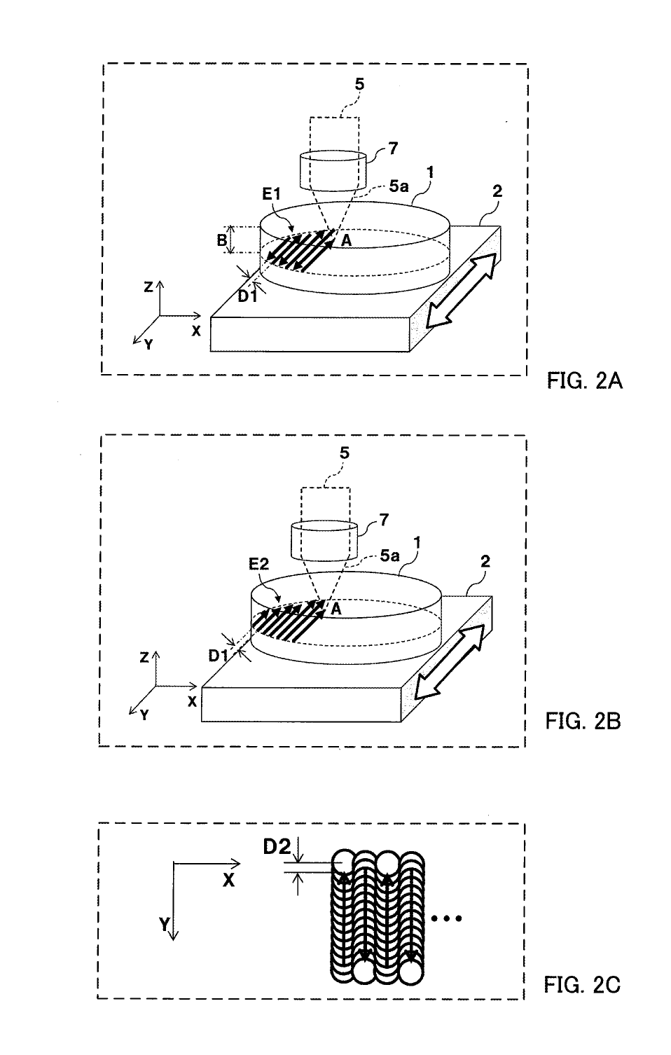

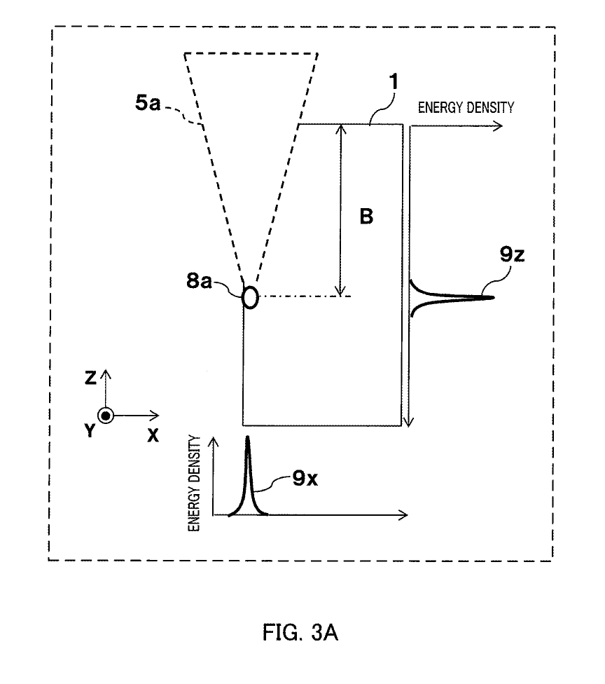

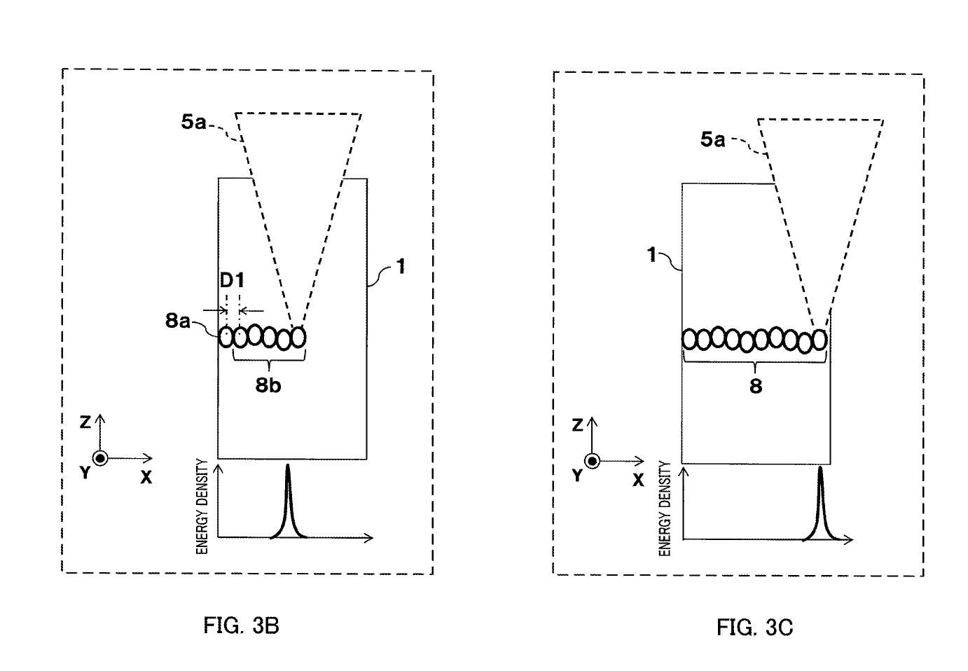

Next, an operation of laser processing apparatus 100 illustrated in FIG. 1 is described with reference to FIG. 2A, FIG. 2B, FIG. 3A, FIG. 3B, and FIG. 3C. FIG. 2A, FIG. 2B, FIG. 3A, FIG. 3B, and FIG. 3C are each a schematic view illustrating a modified-layer forming operation by laser processing apparatus 100.

As described above, laser beam 5a has a transmittance of 50% or more with respect to workpiece 1, and hence laser beam 5a is collected in the vicinity of focus point A with small attenuation. In this case, as an example, distance B between focus point A and the front surface of workpiece 1 is set to a half of the thickness of 400 μm of workpiece 1, that is, 200 μm.

The aberration correction ring of lens 7 is adjusted in accordance with the thickness of workpiece 1, and hence laser beam 5a is converged most at focus point A. As described above, laser beam 5 is picosecond laser. Thus, by a multiphoton absorption process, reaction as in Expression (1) below is generally caused at focus point A, and modified layer 8 is formed.

2GaN→2Ga+N2 (1)

As a result of analysis of materials, in modified layer 8, Ga is mainly generated, and it is found that a Ga dimer and a GaxNy cluster are formed other than Ga. Ga is what is called liquid metal having a melting point Tm=29.8° C.

Workpiece 1 fixed to fixing table 2 is moved relative to laser beam 5a through drive of drive stage 3. With this, the planer modified layer 8 is formed.

FIG. 2A and FIG. 2B each illustrate an example of a moving direction of workpiece 1 (which may be referred to as a scanning direction of laser beam 5a) in the modified-layer forming operation. Arrows E1 and E2 indicate a direction of scanning by irradiating a laser pulse, and the scanning is actually performed as illustrated in FIG. 2C.

Modified layer 8 may be formed as follows. Workpiece 1 is moved repeatedly in a predetermined direction and in an opposite direction in the Y-axis direction while being shifted in the X-axis direction by an amount of line interval D1 as indicated by arrows E1 in FIG. 2A.

Alternatively, modified layer 8 may be formed as follows. Workpiece 1 is moved repeatedly in the same direction in the Y-axis direction while being shifted in the X-axis direction by an amount of line interval D1 as indicated by arrows E2 in FIG. 2B.

Further, laser-irradiation pulse interval D2 in the Y-axis direction indicates an interval of laser pulses adjacent in the scanning direction illustrated in FIG. 2C, and is determined by repetition frequency F of laser oscillator 4 and scanning speed V of drive stage 3. For example, laser-irradiation pulse interval D2 is determined to be a value calculated by Expression (2) below.

D2=V/F (2)

For example, in a case where the repetition frequency is 1,000 kHz and the scanning speed is 1,000 mm/s, modified portions 8a are formed at an interval of 1 μm in the vicinity of focus point A. It is preferred that both of line interval D1 and laser-irradiation pulse interval D2 be smaller than a focal spot diameter of laser beam 5 (for example, 1 μm or smaller). However, focal spot diameters differ depending on an optical system, and hence line interval D1 and laser-irradiation pulse interval D2 are not limited to be smaller than the focal spot diameter.

FIG. 3A to FIG. 3C each illustrate a cross section of workpiece 1 during the modified-layer forming operation.

FIG. 3A illustrates a state of formation of modified layer 8 at an end portion of workpiece 1. 9x indicates an energy density profile in an X direction, and 9z indicates an energy density profile in a Z (depth) direction.

The energy density abruptly increases in the vicinity of the focus point of laser beam 5a in each of the X direction and the Z direction. As a result, a phenomenon called multiphoton absorption occurs. Therefore, laser beam 5a is transmitted at portions other than the focus point, whereas the laser beam is absorbed only at the focus point at which the energy density is high. In this manner, modified portion 8a is formed inside workpiece 1. Modified portion 8a is formed into a linear shape by scanning laser beam 5a in the Y-axis direction.

After the formation of modified portion 8a illustrated in FIG. 3A, as illustrated in FIG. 3B, laser beam 5a is scanned in the X-axis direction a plurality of times at positions shifted in the Y-axis direction by an amount of line interval D1. In this manner, modified portions 8b continuous to each other are formed. Then, finally, as illustrated in FIG. 3C, planar modified layer 8 is formed over entire workpiece 1.

Modified layer 8 formed as described above is influenced by the accuracy of the drive of drive stage 3 and the surface accuracy of fixing table 2 (workpiece 1), and hence has a shape formed with the focus points varied in the Z direction.

In FIG. 3C, as an example, modified layer 8 is illustrated as having a shape with elliptical modified portions 8a and 8b continuous to each other. However, a shape of actually formed modified layer 8 is such that an incident side of laser beam 5a is flat as compared to an emission side of laser beam 5a. This is because the shape of the incident side of laser beam 5a is determined by a position of a focus point that moves slightly in a vertical direction, whereas, on the emission side of laser beam 5a, leakage light that is not used for processing at the focus point is modified in a range exceeding a processing threshold value, and hence it is difficult to determine a modified range.

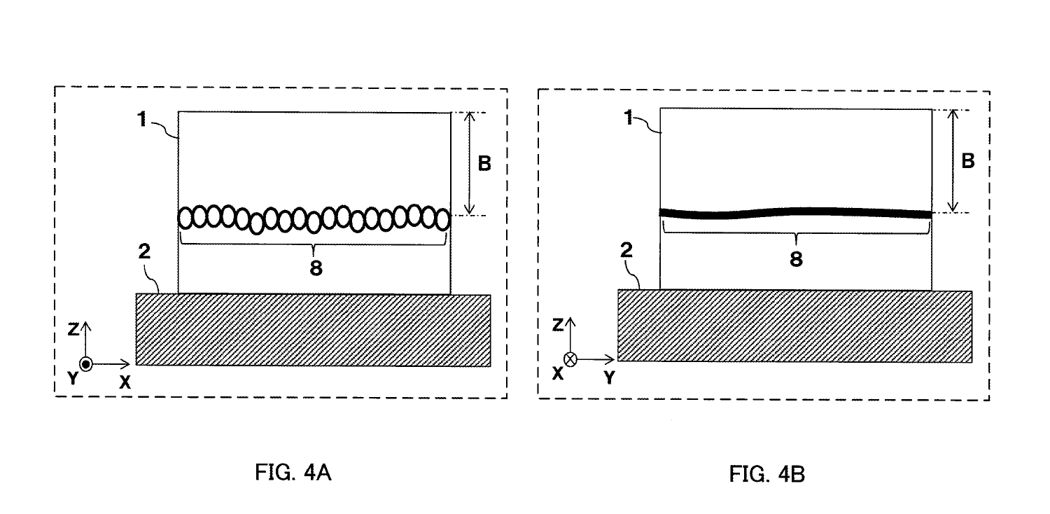

FIG. 4A and FIG. 4B are each a schematic view illustrating a cross section of workpiece 1 having modified layer 8 formed therein. FIG. 4A illustrates a cross section taken along a sub-scanning direction (for example, the X-axis direction) perpendicular to a laser scanning direction (which may be also referred to as a main scanning direction. for example, the Y-axis direction). FIG. 4B illustrates a cross section taken along the Y-axis direction parallel to the laser scanning direction.

Modified layer 8 is formed such that linear modified portions 8a and 8b (see FIG. 3A and FIG. 3B) are continuous to each other. Therefore, as illustrated in FIG. 4A, in the X-axis direction perpendicular to the laser scanning direction, a shape with large irregularities is obtained irrespective of whether or not variation in the Z direction occurs or the degree of the variation. Further, as illustrated in FIG. 4B, in the Y-axis direction parallel to the laser scanning direction, a shape with small irregularities, which is dominantly influenced by the accuracy of drive stage 3 or the surface accuracy of fixing table 2, is obtained.

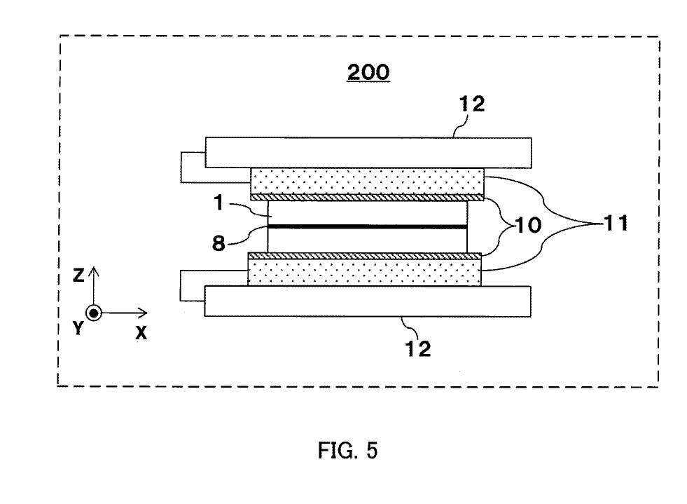

Next, separation apparatus 200 (an example of the slicing apparatus of the present disclosure) for separating workpiece 1 having modified layer 8 formed therein is described with reference to FIG. 5. FIG. 5 is a schematic view of separation apparatus 200 according to this embodiment.

Separation apparatus 200 includes separation jig 11 (an example of a separation section) and heating apparatus 12 (an example of a heating section).

Adhesive sheets 10 each have pressure-sensitive adhesive strength on both surfaces. The pressure-sensitive adhesive strength is lost when adhesive sheets 10 are heated to 120° C. (heat peeling temperature To) or more. As adhesive sheets 10, for example, dicing tapes may be used.

Separation jig 11 is horizontally movable in the X-axis direction, the Y-axis direction, and the Z-axis direction, and is turnable in the θ direction (see FIG. 1). Further, separation jig 11 has a temperature measurement function, and can give the measured temperature to heating apparatus 12 described later as feedback.

Heating apparatus 12 is a contact-type heat source (for example, a hot plate) for heating workpiece 1. Heating apparatus 12 controls a heating temperature to be equal to or more than melting point Tn of modified layer 8 and be less than heat peeling temperature To of adhesive sheets 10 based on the temperature measured by separation jig 11. Note that, the main component of modified layer 8 is gallium (Ga), and hence it may be regarded that melting point Tn of modified layer 8=melting point Tm of Ga.

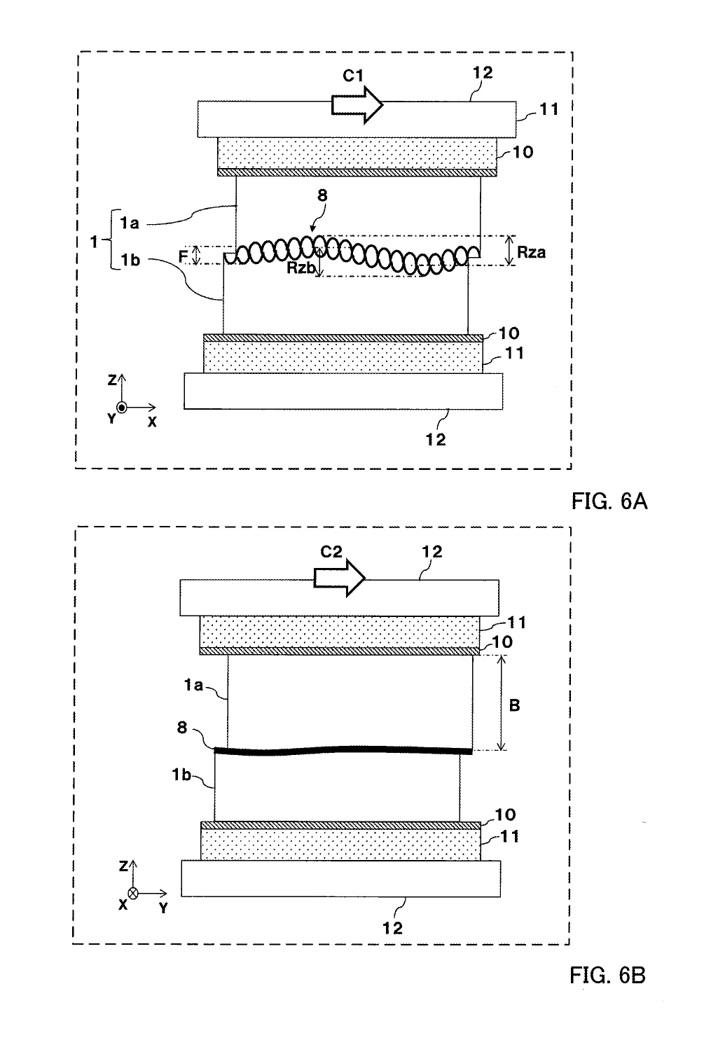

Next, an operation of the separation apparatus illustrated in FIG. 5 is described with reference to FIG. 6A and FIG. 6B. FIG. 6A and FIG. 6B are each an explanatory schematic view of a workpiece separating operation by the separation apparatus.

Modified layer 8 is melted when being heated by heating apparatus 12 to be equal to or more than melting point Tn. At this time, using separation jig 11, a load is applied in a direction substantially parallel to an XY plane on which modified layer 8 is formed, and upper wafer 1a of workpiece 1 (hereinafter, simply referred to as an upper portion) and lower wafer 1b of workpiece 1 (hereinafter, simply referred to as a lower portion) with respect to modified layer 8 as a boundary are shifted in the direction substantially parallel to the XY plane. With this, workpiece 1 is separated into upper portion 1a and lower portion 1b.

Further, the pressure-sensitive adhesive strength of adhesive sheets 10 is lost when adhesive sheets 10 are heated by heating apparatus 12 to be equal to or more than heat peeling temperature To. With this, upper portion 1a and lower portion 1b after being separated from each other can be peeled from separation jig 11.

FIG. 6A illustrates a case in which upper portion 1a and lower portion 1b are shifted in the C1 direction (X-axis direction perpendicular to the laser scanning direction). As described above, modified layer 8 is incited by being heated by heating apparatus 12, and irregular portions remain in a direction perpendicular to the C1 direction (Z direction) at an unmodified portion at a peripheral edge of modified layer 8 (which may be referred to as a GaN portion). Therefore, as illustrated in FIG. 6A, in the case where upper portion 1a and lower portion 1b are shifted in the C1 direction, the irregular portions of upper portion 1a and the irregular portions of lower portion 1b interfere with each other. Thus, upper portion 1a and lower portion 1b cannot be shifted sufficiently, so that workpiece 1 cannot be separated into upper portion 1a and lower portion 1b.

Meanwhile, FIG. 6B illustrates a case where upper portion 1a and lower portion 1b are shifted in the C2 direction (Y-axis direction parallel to the laser scanning direction). Irregular portions are only slightly formed in the laser scanning direction. Even in a case where the irregular portions are formed in the laser scanning direction, the irregular portions have a gentle irregular shape influenced by the accuracy of drive stage 3 or the surface accuracy of fixing table 2. Therefore, as illustrated in FIG. 6B, in a case where upper portion 1a and lower portion 1b are shifted in the C2 direction, interference between the irregular portions of upper portion 1a and the irregular portions of lower portion 1b is less liable to occur. Therefore, workpiece 1 can be separated into upper portion 1a and lower portion 1b.

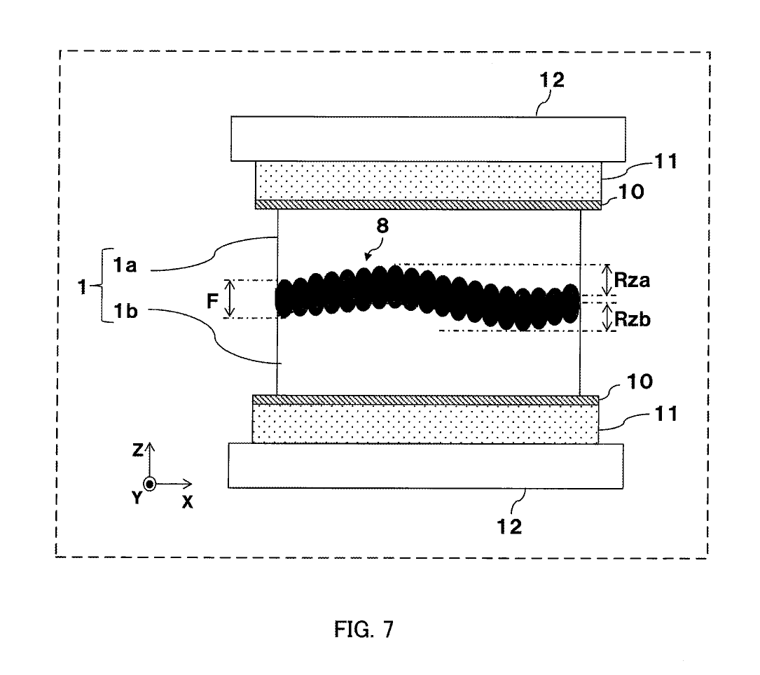

Further, as illustrated in FIG. 7, in a case where a surface roughness of an unmodified layer of upper portion 1a (length in the Z direction) is represented by Rza, a surface roughness of an unmodified layer of lower portion 1b (length in the Z direction) is represented by Rzb, and a thickness of modified layer 8 (length in the Z direction) is represented by F, modified layer 8 is formed so as to satisfy relationships of F>Rza and F>Rzb. Furthermore, it is preferred to form modified layer 8 in which thickness F is larger than surface roughnesses Rza and Rzb by 10% or more. With this, an influence of the interference caused by the irregular portions described above can be reduced, and more stable separation can be achieved.

For example, in a case where thickness F is about 10 and surface roughnesses Rza and Rzb are each about 20 μm, it is difficult to separate upper portion 1a and lower portion 1b from each other. Therefore, in this case, it is preferred to form modified layer 8 so that thickness F is larger than 20 μm. In order to obtain such thickness F, it is required to increase a region in which the energy density exceeds the processing threshold value in the vicinity of the focus point. Therefore, it is only required to increase power of laser beam 5a or use a lens having a slightly small numerical aperture (NA).

Next, an inclination during the separation is described.

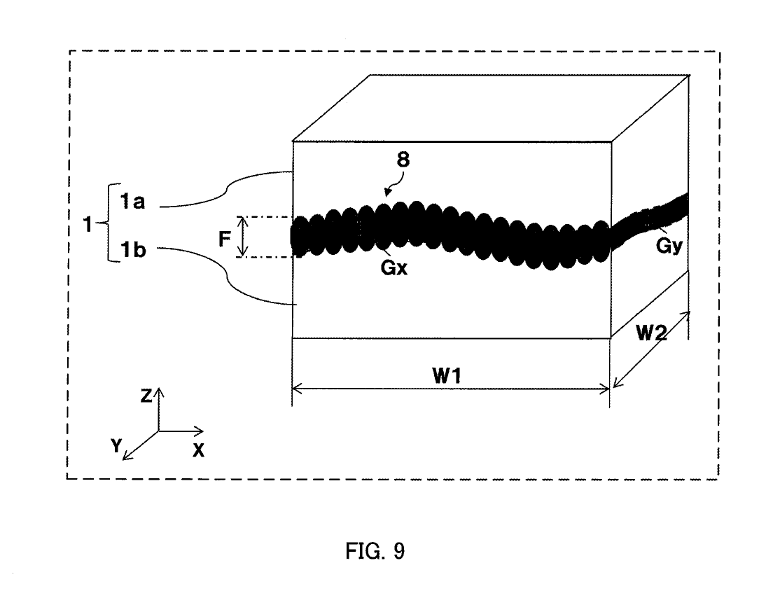

FIG. 9 is a perspective view of workpiece 1 having the modified layer formed therein. In thickness F of the modified layer, a thickness of a portion connecting adjacent portions each scanned with laser in an XZ plane is represented by Gx, and a thickness of a portion connecting adjacent portions each scanned with laser in a YZ plane is represented by Gy. Further, a dimension of workpiece 1 in the X direction is represented by W1, and a dimension of workpiece 1 in the Y direction is represented by W2.

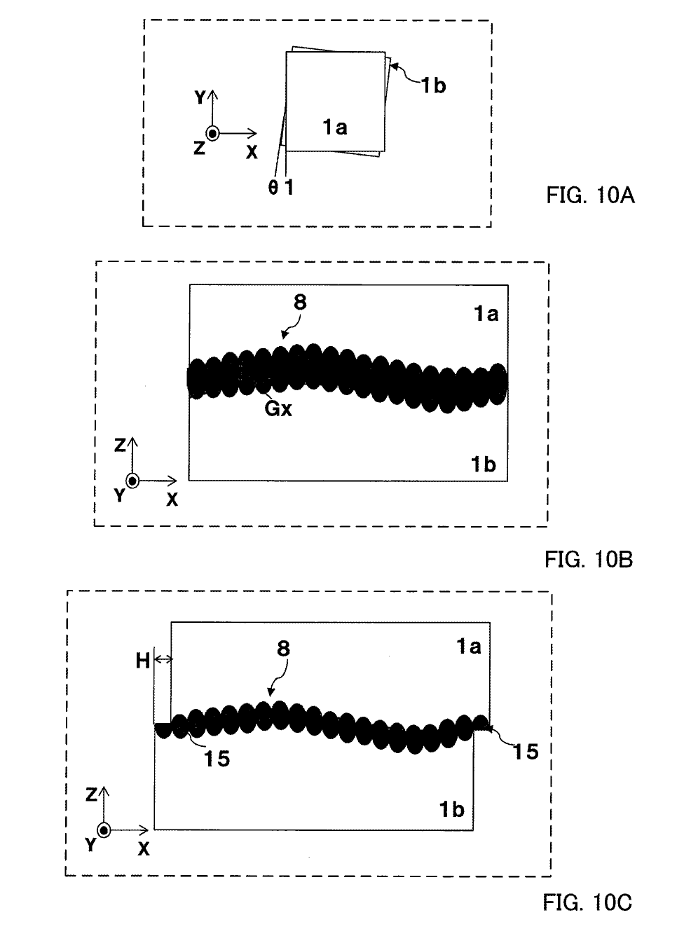

FIG. 10A is a schematic \ illustrating a state in which upper portion 1a and lower portion 1b of workpiece 1 are turned in the horizontal direction as viewed from directly above. FIG. 10B is a schematic view illustrating a state before an end surface of workpiece 1 in the XZ plane is turned. FIG. 10C is a schematic view illustrating a state after the end surface illustrated in FIG. 10B is turned.

When lower portion 1b is shifted with respect to upper portion 1a by distance H as illustrated in FIG. 10C, upper portion 1a and lower portion 1b are turned at angle θ1 as illustrated in FIG. 10A. With this, collision point 15 illustrated in FIG. 10C is generated, and upper portion 1a and lower portion 1b cannot be turned anymore. Angle θ1 can be expressed by Expression (3) below.

θ1=tan−1(H/W2)≈H/W2[rad] (3)

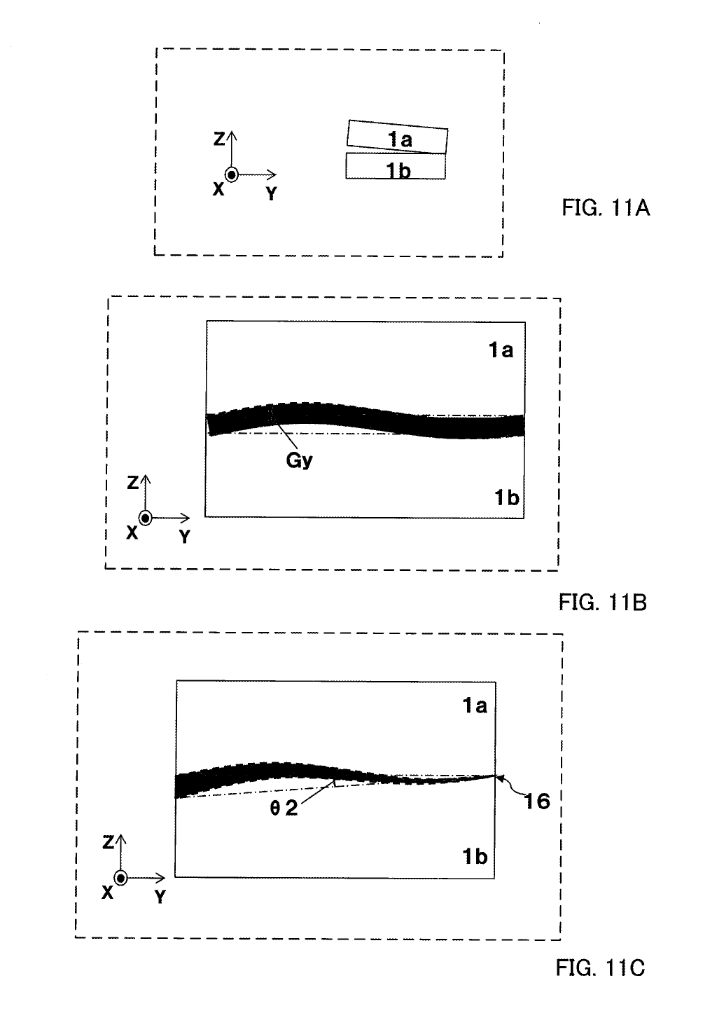

FIG. 11A is a schematic view illustrating a state in which upper portion 1a and lower portion 1b are inclined in the Z direction. FIG. 11B is a schematic view illustrating a state before an end surface of workpiece 1 in the YZ plane is inclined. FIG. 11C is a schematic view illustrating a state after the end surface illustrated in FIG. 11B is inclined.

As illustrated in FIG. 11A, when lower portion 1b is inclined with respect to upper portion 1a at angle θ2 illustrated in FIG. 11C, collision point 16 illustrated in FIG. 11C is generated, and lower portion 1b cannot be inclined anymore. Angle θ2 can be expressed by Expression (4) below.

θ2=tan−1(Gy/W2)≈Gy/W2[rad] (4)

For example, in a case where relationships of thickness Gx=Gy=5 μm, H=10 and W1=W2=50 mm are satisfied, the following relationships are satisfied,

θ1=H/W2=10/(50×1,000)=0.2 mrad

θ2=Gy/W2=5/(50×1,000)=0.1 mrad.

That is, in an intermediate state between the state illustrated in FIG. 10B and the state illustrated in FIG. 10C or an intermediate state between the state illustrated in FIG. 11B and the state illustrated in FIG. 11C, the relative positions between upper portion 1a and lower portion 1b can be changed, and the wafers can be separated. Therefore, this state can be defined as being substantially parallel.

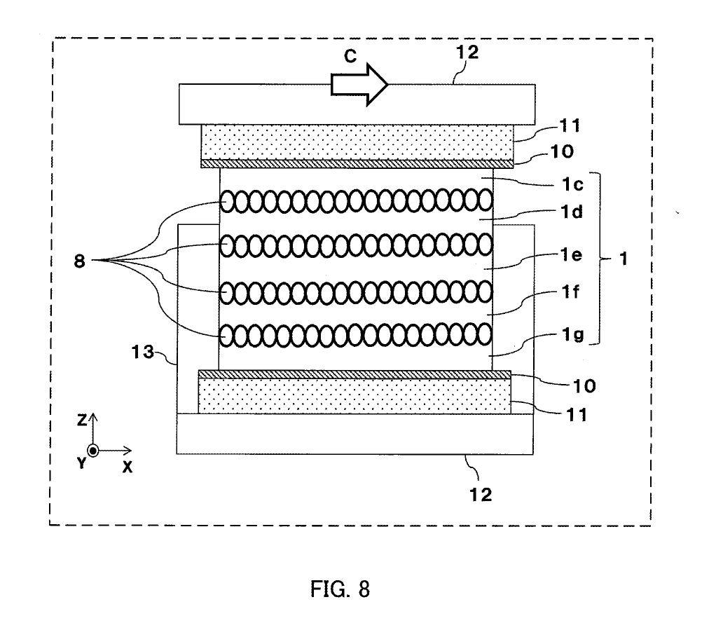

In the description above, the case in which one modified layer 8 is formed is described as an example. However, plurality of modified layers 8 may be formed. Hereinafter, this case is described with reference to FIG. 8. FIG. 8 is a schematic view illustrating a cross section of workpiece 1 having plurality of modified layers 8 formed therein.

In FIG. 8, pressing section 13 can be adjusted to any height of wafers 1c, 1d, 1e, 1f, and 1g after workpiece 1 is sliced, and has strength that overcomes a separation load in the C direction.

In FIG. 8, as an example, a case where pressing section 13 is adjusted to the height of wafer 1d in order to separate wafer 1c is illustrated. Downward displacement of wafers 1d to 1g below wafer 1c when a load is applied in the C direction is suppressed, so that the load in the C direction acts to separate a modified layer between wafer 1c and wafer 1d, and thus, only wafer 1c can be separated.

After wafer 1c is separated, a front surface of wafer 1d is polished. After that, the remaining part of workpiece 1 is fixed by adhesive sheets 10 again to change a position of pressing section 13 to the height of wafer 1e. With this, wafer 1d can be separated.

Note that, the operation described above is repeatedly performed also on wafers 1e to 1a, so that wafers 1e to 1g can be separated. Wafers 1c to 1g after being separated from each other are polished in a subsequent step, and modified layers 8 are removed. With this, wafers 1c to 1g can each be used as a GaN wafer.

As described above, this embodiment has a feature in that modified layers 8 of workpiece 1 formed by laser beam 5a collected thereto are heated at a temperature that is less than the melting point of workpiece 1 and equal to or more than the melting point of modified layers 8, so that modified layers 8 are melted, and workpiece 1 is separated at melted modified layers 8 as boundaries.

With this, in this embodiment, after the modified layers are formed inside the workpiece, a trouble that occurs when the workpiece is separated at the modified layers as boundaries (for example, chipping, crack, or breakage) can be suppressed. Therefore, a yield of the separation can be enhanced. Further, a polishing amount can be reduced in the subsequent step, and hence it can be expected to reduce material loss.

Note that, the present disclosure is not limited to the description of the embodiment described above, and various modifications may be made without departing from the gist of the present disclosure. Hereinafter, Modification Examples are described.

### Modification Example 1

In the embodiment, linear scanning in the Y-axis direction is described as an example, but the present invention is not limited thereto. For example, there may be employed linear scanning in the X-axis direction, turning scanning about the θ axis, or arc scanning in which workpiece 1 is installed at a position eccentrically displaced from the turning center being the θ axis. Note that, in a case of employing the X-axis scanning, similarly to the embodiment described above, workpiece 1 can be separated. However, in a case of employing the turning scanning or the arc scanning, when workpiece 1 is to be separated, it is required to apply the separation load in the turning direction or the arc direction.

### Modification Example 2

In the embodiment, the case of using the contact-type heat source as heating apparatus 12 is described as an example, but heating apparatus 12 may be a non-contact-type heat source. For example, as the non-contact-type heat source, there may be used a light source that emits light having a transmittance of 80% or more with respect to workpiece 1 and causes modified layer 8 to indicate absorbability of 50% or more (for example, an IR heater or a halogen lamp). Also in this case, similarly to the embodiment, separation with heating of Ga precipitated on the modified portion can be enabled.

### Modification Example 3

In the embodiment, the case in which the heating temperature of heating apparatus 12 is equal to or more than melting point Tn of modified layer 8 and is less than heat peeling temperature To of adhesive sheets 10 is described as an example, but the present invention is not limited thereto. For example, in a case of not using adhesive sheets 10 (for example, a case where workpiece 1 is fixed onto the support substrate so as not to be peeled or a case where workpiece 1 is fixed by vacuum suction), it is only required that the heating temperature be set to be equal to or more than melting point Tn of modified layer 8 and less than a melting point of workpiece 1 (GaN substrate).

### Modification Example 4

In the embodiment, the case of using workpiece 1 having a diameter of 2 inches and a thickness of 400 μm and formed of gallium nitride is described as an example. However, the diameter, the thickness, and the material are not limited thereto. The material of workpiece 1 may be, for example, a silicon substrate, a sapphire substrate, a substrate obtained by epitaxially growing a GaN layer on a sapphire substrate, a gallium arsenide (GaAs) substrate, an indium phosphide (InP) substrate, an aluminum nitride gallium (AlGaN)/GaN substrate, a SiC substrate, a substrate obtained by epitaxially growing a GaN layer on a SiC substrate, or diamond. That is, any material may be applied as long as the material allows transmission of a laser beam and can form a modified layer. However, a material in which a melting point of a modified layer is low (for example, GaN) is preferably used.

### Modification Example 5

In the embodiment, the case where the wavelength of laser beam 5 emitted from laser oscillator 4 is 532 nm is described as an example. However, the wavelength of laser beam 5 is not limited thereto, and is only required to have a transmittance with respect to workpiece 1. Note that, a shorter wavelength is preferred because dimensions of focus point A inside workpiece 1 in the thickness direction and the horizontal direction are reduced, and processability is enhanced.

### Modification Example 6

In the embodiment, the case where the pulse width of laser beam 5 is equal to or more than 0.2 picoseconds and equal to or less than 100 picoseconds, and the maximum repetition frequency of laser beam 5 is 1 MHz is described as an example. However, the present invention is not limited thereto. For example, the pulse width of laser beam 5 is only required to fall within a range of from 1 femtosecond (fs) or more to 1 nanosecond (ns) or less and allow internal processing by multiphoton absorption. It is only required that the repetition frequency of laser beam 5 be selected in a range of 10 MHz or less, which can be emitted from laser oscillator 4, in consideration of processability that is mutually influenced by workpiece 1 and laser beam 5 and productivity.

### Modification Example 7

In the embodiment, the case where the numerical aperture of lens 7 is 0.7 is described as an example. However, the numerical aperture of lens 7 is not limited thereto, and is only required to be 0.4 or larger and 0.95 or smaller. Note that, it is preferred that the numerical aperture of lens 7 be larger in order to reduce the diameter of focus point A. As lens 7, it is desired to use a lens with an aberration correction function because the energy density of focus point A can be increased. However, the present invention is not limited thereto, and, for example, aberration correction may be performed in advance by a phase modulation element or a lens.

### Modification Example 8

Further, the modified-layer forming operation and the workpiece separating operation described in the embodiment may be applied to, for example, a case of processing workpiece 1 by irradiating laser beam 5 to a plurality of portions of workpiece 1 at the same time using a mirror, a diffraction optical element, or a phase modulation element. In this case, a processing time can be shortened, and the productivity is further improved.

### INDUSTRIAL APPLICABILITY

The slicing method and the slicing apparatus according to the present disclosure can be applied to the whole field of technology of forming a modified layer inside a hard brittle material using laser and separating the hard brittle material into a wafer shape at the modified layer as a boundary.

### REFERENCE SIGNS LIST

1 Workpiece
1a Upper wafer of workpiece 1
1b Lower wafer of workpiece 1
1c, 1d, 1e, 1f, 1g Wafer
2 Fixing table
3 Drive stage
4 Laser oscillator
5, 5a Laser beam
6 Mirror
7 Lens
8 Modified layer
8a, 8b Modified portion
10 Adhesive sheet
11 Separation jig
12 Heating apparatus
13 Pressing section
15, 16 Collision point
100 Laser processing apparatus
200 Separation apparatus

1. A slicing method, comprising:
a modified-layer melting step of melting a modified layer of a workpiece by heating the modified layer at a temperature that is less than a melting point of the workpiece and is equal to or more than a melting point of the modified layer, the workpieces being formed by collection of a laser beam; and
a separating step of separating the workpiece at the melted modified layer as a boundary.

2. The slicing method according to claim 1, wherein a thickness of the modified layer is larger than a surface roughness of an unmodified layer of the workpiece.

3. The slicing method according to claim 1, wherein, in the separating step, the workpiece is separated in a direction parallel to a scanning direction of the laser beam.

4. The slicing method according to claim 1, wherein a pulse width of the laser beam is equal to or more than 0.2 picoseconds and equal to or less than 100 picoseconds.

5. The slicing method according to claim 4, wherein the laser beam has a wavelength with a transmittance of 50% or more with respect to the workpiece.

6. A slicing apparatus, comprising:
a heating section that melts a modified layer of a workpiece by heating the modified layer at a temperature that is less than a melting point of the workpiece and is equal to or more than a melting point of the modified layer, the workpieces being formed by collection of a laser beam; and
a separation section that separates the workpiece at the melted modified layer as a boundary.
